(19) United States
(12) Patent Application Publication
(10) Pub. No.: US 2014/0225216 A1
(43) Pub. Date: Aug. 14, 2014

(54) PHOTODETECTOR

(71) Applicant: FUJITSU LIMITED, Kawasaki-shi (JP)

(72) Inventors: SHINICHIRO KAWAKAMI, Kawasaki (JP); Yasuo MATSUMIYA, Kawasaki (JP)

(73) Assignee: FUJITSU LIMITED, Kawasaki-shi (JP)

(21) Appl. No.: 14/253,064

(22) Filed: Apr. 15, 2014

Related U.S. Application Data
(62) Division of application No. 13/282,760, filed on Oct. 27, 2011.

(30) Foreign Application Priority Data
Oct. 28, 2010 (JP) 2010-241587

(51) Int. Cl. H01L 31/108; H01L 27/146

(52) U.S. Cl. CPC H01L 31/108; H01L 27/14649
USPC 257/453

(57) ABSTRACT

A photodetector includes a substrate, a first electrode layer, a first light absorbing layer, a second electrode layer, a second light absorbing layer, and a third electrode layer that are laminated on the substrate, a first electrode wire that intercouples the first electrode layer and the second electrode layer, a second electrode wire that intercouples the second electrode layer and the third electrode layer, a first diode formed at a place where the second electrode layer and the first electrode wire are mutually brought into contact, and a second diode formed at a place where the second electrode layer and the second electrode wire are mutually brought into contact.

### CROSS-REFERENCE TO RELATED APPLICATIONS

This application is a divisional of application Ser. No. 13/282,760, filed Oct. 27, 2011, which is based upon and claims the benefit of priority from the prior Japanese Patent Application No. 2010-241587 filed on Oct. 28, 2010, the entire contents of which are incorporated herein by reference.

### FIELD

The present invention relates to a photodetector.

### BACKGROUND

Photodetectors include a photosensor that detects infrared light. When photosensors of this type are two-dimensionally arranged, an infrared image sensor is formed. Infrared Physics & Technology 50 (2007) 217-226 describes a quantum well infrared image sensor that can detect two infrared light rays with different wavelengths. The infrared image sensor of this type will be described with reference to FIG. 1.

The infrared image sensor has a substrate 211 such as a semiconductor on which a lower electrode layer 212, a first light absorbing layer 213, an intermediate electrode layer 214, a second light absorbing 215, an upper electrode layer 216, and an insulating layer 217 are laminated in that order for each pixel. Three electrode parts 221, 222, and 223, called bumps, are provided on the insulating layer 217 for each pixel, each of which is made of a metal material. The electrode part 221 is coupled to the upper electrode layer 216 through an ohmic contact 224 formed in an opening of the insulating layer 217. The electrode part 222 is coupled to an electrode wire 226, which is coupled to the intermediate electrode layer 214 through an ohmic contact 225. The electrode part 223 is coupled to an electrode wire 228, which is coupled to the lower electrode layer 212 through an ohmic contact 227.

When the infrared image sensor detects infrared light, the electrode part 222 applies a bias voltage to the intermediate electrode layer 214 through the electrode wire 226. If infrared light is directed from the substrate 211 in this state, a photocurrent output generated in the second light absorbing 215 is retrieved from the electrode part 221 through the upper electrode layer 216. A photocurrent output generated in the first light absorbing layer 213 is retrieved from the 223 through the lower electrode layer 212 and electrode wire 228. One side of a chip that includes an infrared image sensor having this structure is about 41.0 mm long when the infrared image sensor has 1024×1024 pixels with a pixel pitch of 40 μm.

Infrared Physics & Technology 52 (2009) 395-398 describes an infrared image sensor structured so as to have two electrode parts for each pixel as shown in FIG. 2 as a photodetector structured so as to reduce the number of electrode parts per pixel. The infrared image sensor of this type has a substrate 251 such as a semiconductor on which a lower electrode layer 252, a first light absorbing layer 253, a first intermediate electrode layer 254, an insulating layer 255, a second intermediate electrode layer 256, a second light absorbing 257, an upper electrode layer 258, and an insulating layer 259 are laminated in that order for each pixel. Two electrode parts 261 and 262 are provided on the insulating layer 259 for each pixel, each of which is made of a metal material. The electrode part 261 is coupled to the upper electrode layer 258 through an ohmic contact 263 formed in an opening of the insulating layer 259. The electrode part 262 is coupled to an electrode wire 265, which is coupled to the first intermediate electrode layer 254 through an ohmic contact 264. The second intermediate electrode layer 256 and lower electrode layer 252 are intercoupled through an electrode wire 266. An ohmic contact 267 is provided between the second intermediate electrode layer 256 and the electrode wire 266, and an ohmic contact 268 is provided between the lower electrode layer 252 and the electrode wire 266. An electrode part 269 is provided on the lower electrode layer 252. In the infrared image sensor having the structure described above, only the electrode parts 261 and 262 are formed for each pixel, so the number of electrode parts per pixel can be reduced to two.

When the infrared image sensor having this structure detects infrared light, the electrode part 269 applies a bias voltage to the lower electrode layer 252, in which case the bias voltage is also applied to the second intermediate electrode layer 256, which is coupled to the lower electrode layer 252 through the electrode wire 266. If infrared light is directed from the substrate 251 in this state, a photocurrent output generated in the second light absorbing 257 is retrieved from the electrode part 261 through the upper electrode layer 258. A photocurrent output generated in the first light absorbing layer 253 is retrieved from the electrode part 262 through the first intermediate electrode layer 254.

Since an infrared image sensor having this structure can reduce the number of electrode parts per pixel to two, the pixel pitch can be reduced to about 30 μm. Accordingly, when the infrared image sensor has 1024×1024 pixels, one side of a chip that includes the infrared image sensor can be reduced to about 30.7 mm.

### SUMMARY

According to aspects of embodiments, a photodetector includes a substrate, a first electrode layer, a first light absorbing layer, a second electrode layer, a second light absorbing layer, and a third electrode layer that are laminated on the substrate, a first electrode wire that intercouples the first electrode layer and the second electrode layer, a second electrode wire that intercouples the second electrode layer and the third electrode layer, a first diode formed at a place where the second electrode layer and the first electrode wire are mutually brought into contact, and a second diode formed at a place where the second electrode layer and the second electrode wire are mutually brought into contact.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 depicts a photodetector of related art;

FIG. 2 depicts another photodetector of related art;

FIG. 3 depicts the structure of a photodetector in an embodiment;

FIG. 4 depicts an equivalent circuit of the photodetector in the embodiment;

FIGS. 5A and 5B illustrate the photodetector in the embodiment;

FIGS. 6A to 6Z depict processes of manufacturing the photodetector in the embodiment;

FIG. 7 depicts the structure of a photodetector in another embodiment;

FIG. 8 depicts an equivalent circuit of the photodetector in the other embodiment;

FIGS. 9A and 9B illustrate the photodetector in the other embodiment;

FIGS. 10A and 10B depict the structure of the photodetector in the other embodiment; and

FIG. 11 illustrates the semiconductor layers of the photodetector in the other embodiment.

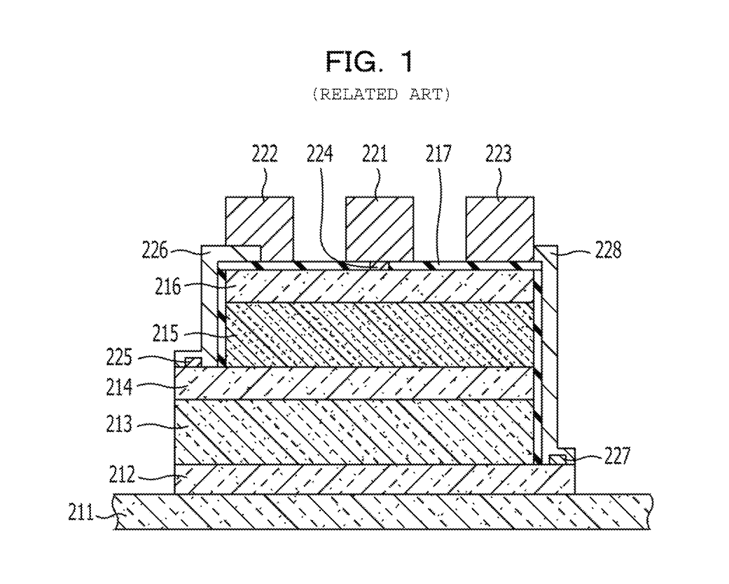

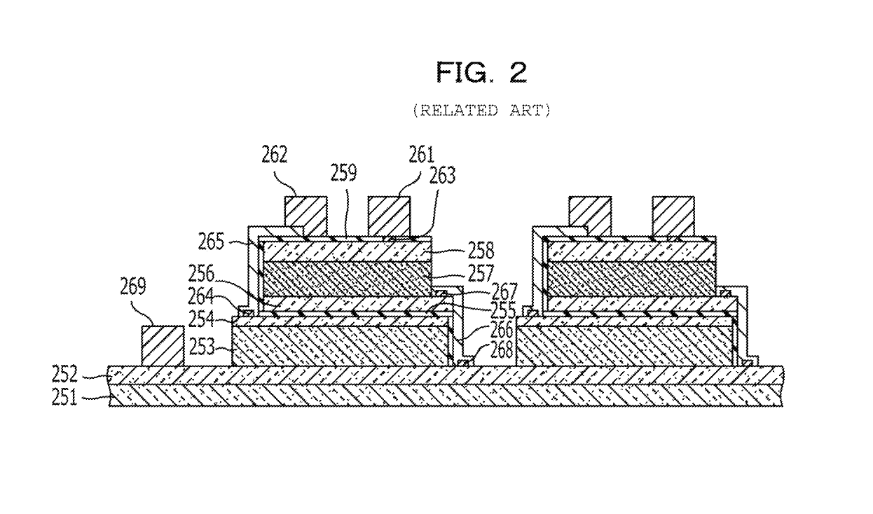

### DESCRIPTION OF EMBODIMENTS

Preferred embodiments will be explained with reference to accompanying drawings. With the quantum well infrared image sensor described in Infrared Physics & Technology 50 (2007) 217-226, three electrode parts need to be formed for each pixel, so it is difficult to reduce the size of one pixel and thereby it becomes difficult to make the entire infrared image sensor compact and increase its resolution. If, for example, electrode parts, which are bumps, are formed at a high density, flip chip bonding is hard to carry out and thereby loose contacts and other problems may be caused.

Embodiments of this disclosure will be described below. However, like elements are denoted by like reference numerals, and repeated descriptions are omitted.

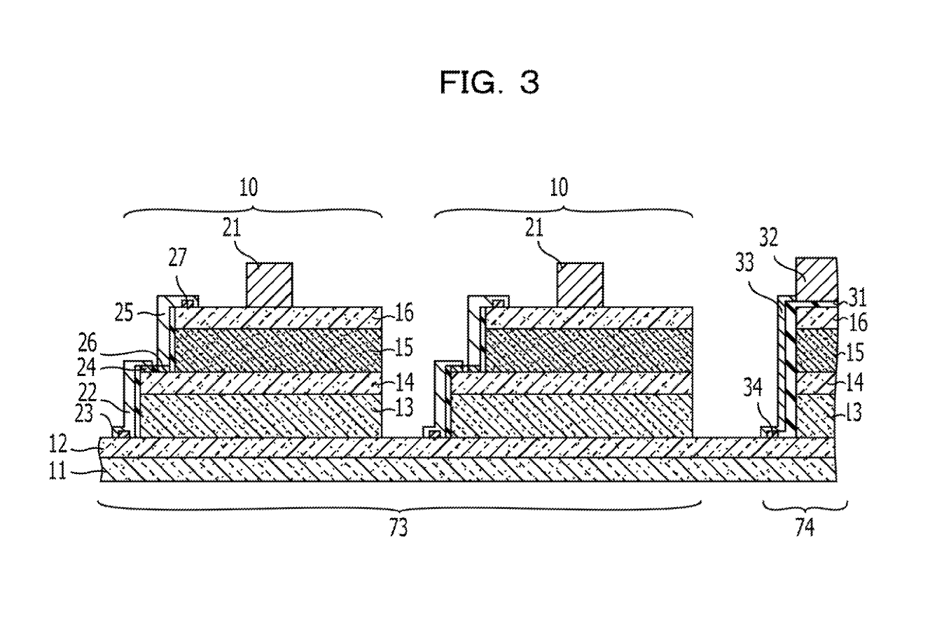

The structure of an image sensor that may detect two infrared rays with different wavelengths, which is the photodetector in an embodiment, will be described with reference to FIG. 3.

The infrared image sensor in this embodiment has a substrate 11 such as a semiconductor on which a lower electrode layer 12, a first light absorbing layer 13, an intermediate electrode layer 14, a second light absorbing 15, and an upper electrode layer 16 are laminated in that order. In this embodiment, the lower electrode layer 12 may be a first electrode layer, the intermediate electrode layer 14 may be a second electrode layer, and the upper electrode layer 16 may be a third electrode layer.

A plurality of pixel areas 10 may be formed on a pixel forming area 73. One electrode part 21 referred to as a bump, which is made of a metal or another material, may be formed for each pixel on the upper electrode layer 16 in each pixel area 10. The electrode part 21 may be coupled to the upper electrode layer 16. A first electrode wire 22 may be provided between the lower electrode layer 12 and the intermediate electrode layer 14. An ohmic contact 23 may be provided between the first electrode wire 22 and the lower electrode layer 12. A Schottky contact 24 may be provided between the first electrode wire 22 and the intermediate electrode layer 14.

A second electrode wire 25 may be provided between the intermediate electrode layer 14 and the upper electrode layer 16. A Schottky contact 26 may be provided between the second electrode wire 25 and the intermediate electrode layer 14. An ohmic contact 27 may be provided between the second electrode wire 25 and the upper electrode layer 16.

Furthermore, in a non-pixel area 74, an electrode part 32 may be formed on an insulating layer 31 formed on the upper electrode layer 16. The electrode part 32 may be coupled to an electrode wire 33. The electrode wire 33 may be ohmically coupled to an ohmic contact 34 provided on the surface of the lower electrode layer 12. The electrode part 32 may be a common bias electrode terminal and may not be provided for each pixel. Accordingly, in the infrared image sensor in this embodiment, electrode parts formed for each pixel may be the electrode part 21 alone, so the number of electrode parts per pixel may be one.

In general, the lower electrode layer 12, intermediate electrode layer 14, and upper electrode layer 16 may be each formed as a low-resistance semiconductor doped with an impurity at a high density to about 10×10¹⁸ cm⁻³. However, there are cases in which it is hard for a semiconductor layer doped with an impurity element at a high density to provide a superior Schottky barrier junction. In the intermediate electrode layer 14, therefore, a layer doped with an impurity element at a low density may be formed in an area in which the Schottky contacts 24 and 26 are formed so that a Schottky barrier junction is provided.

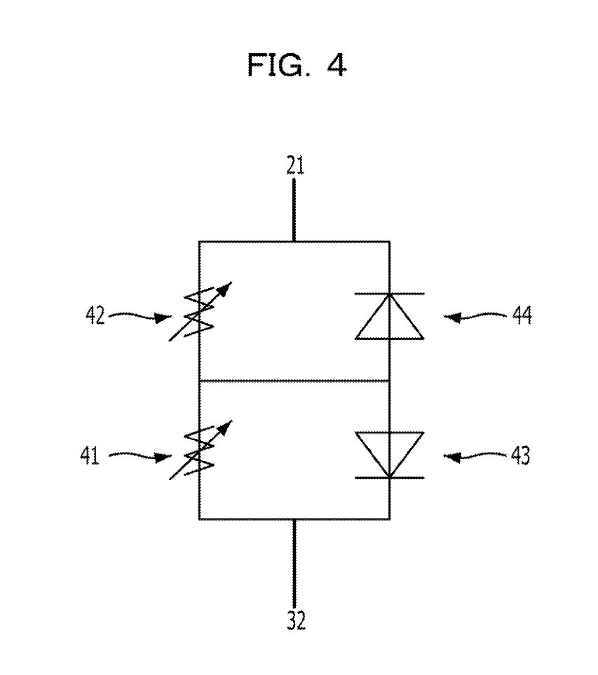

FIG. 4 depicts an equivalent circuit of the photodetector in this embodiment. A first photodetector part 41 may be formed with the lower electrode layer 12, the first light absorbing layer 13, and the intermediate electrode layer 14, and a second photodetector 42 may be formed with the intermediate electrode layer 14, the second light absorbing 15, and the upper electrode layer 16. A first Schottky barrier diode 43 may be formed with the intermediate electrode layer 14 and the Schottky contact 24. A second Schottky barrier diode 44 may be formed with the intermediate electrode layer 14 and the Schottky contact 26. The first Schottky barrier diode 43 may be a first diode and the second Schottky barrier diode 44 may be a second diode.

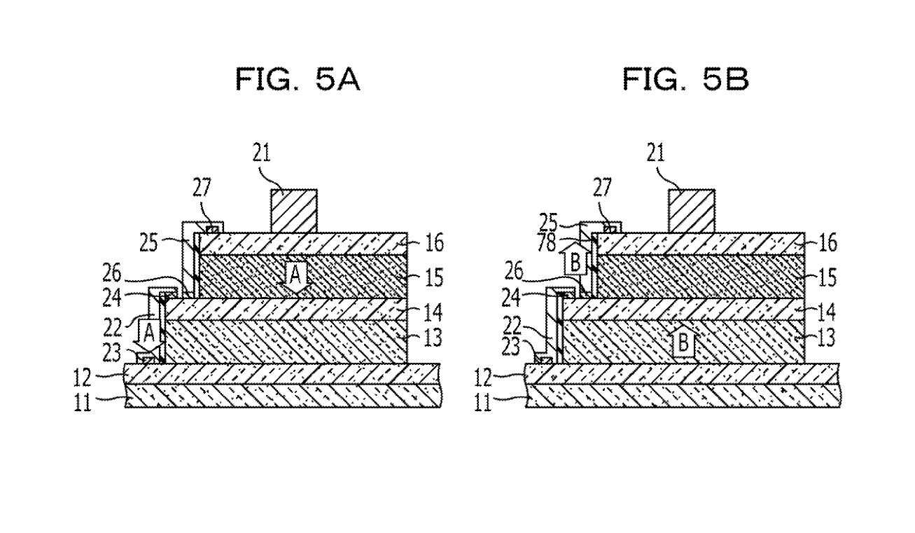

If, in this photodetector, a bias voltage is applied so that the electrode part 32 has a smaller electric potential than the electrode part 21, a current flows in the second photodetector 42 and first Schottky barrier diode 43. This makes it possible to obtain an output corresponding to light detected by the second photodetector 42. FIG. 5A indicates a current flow by using an arrow A while the photodetector in this embodiment is placed in this state. If a bias voltage is applied so that the electrode part 32 has a higher electric potential than the electrode part 21, a current flows in the first photodetector part 41 and second Schottky barrier diode 44. This makes it possible to obtain an output corresponding to light detected by the first photodetector part 41. FIG. 5B indicates a current flow by using an arrow B while the photodetector in this embodiment is placed in this state.

A switchover may be made between the output detected by the first photodetector part 41 and the output detected by the second photodetector 42 by changing the bias voltage applied between the electrode part 21 and the electrode part 32 from the positive level to the negative level and vice versa as described above. Accordingly, it is possible to obtain an infrared image sensor that may detect two infrared rays having different wavelengths with only one electrode part formed for one pixel.

As described above, Infrared Physics & Technology 52 (2009) 395-398 describes an infrared image sensor that have two electrode parts for each pixel at a pixel pitch of 30 μm. Therefore, if the electrode parts are diagonally disposed, the distance between the electrode parts may be about 21 μm (30×21/2/2 μm). If this value of the distance is used, the pixel pitch in an infrared image sensor having a single electrode part is 21 μm, so the size of a chip that includes an infrared image sensor having 1024×1024 pixels may be about 22 square millimeters. Accordingly, the infrared image sensor in this embodiment may be made smaller than a chip size of 30.7 square millimeters measured for the infrared image sensor described in Infrared Physics & Technology 52 (2009) 395-398 and a chip size of 41.0 square millimeters measured for the infrared image sensor described in Infrared Physics & Technology 50 (2007) 217-226.

Therefore, more chips may be manufactured from a single wafer and the manufacturing cost of the infrared image sensor may be thereby reduced.

Next, the method of manufacturing the infrared image sensor in this embodiment will be described.

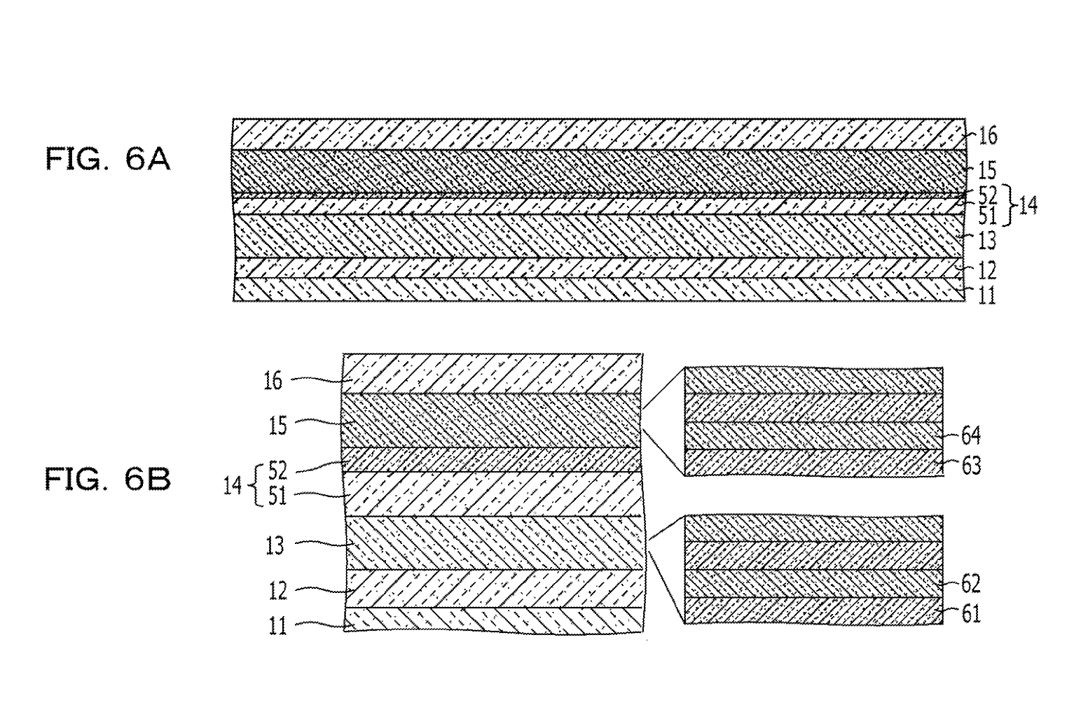

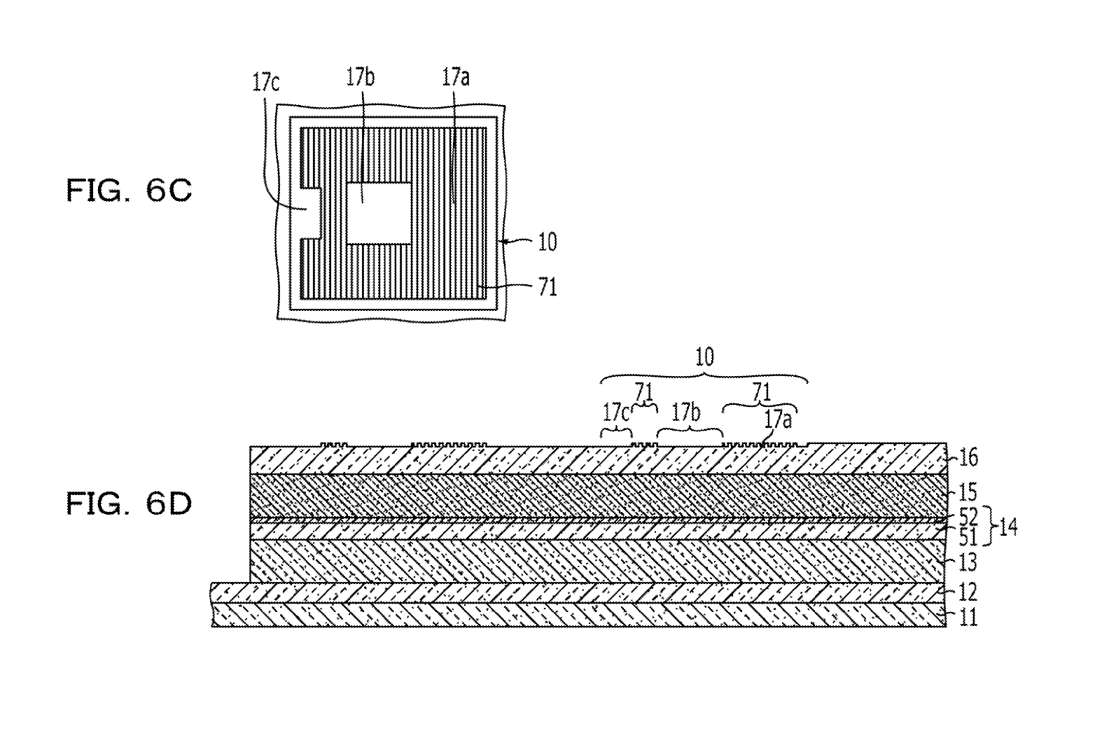

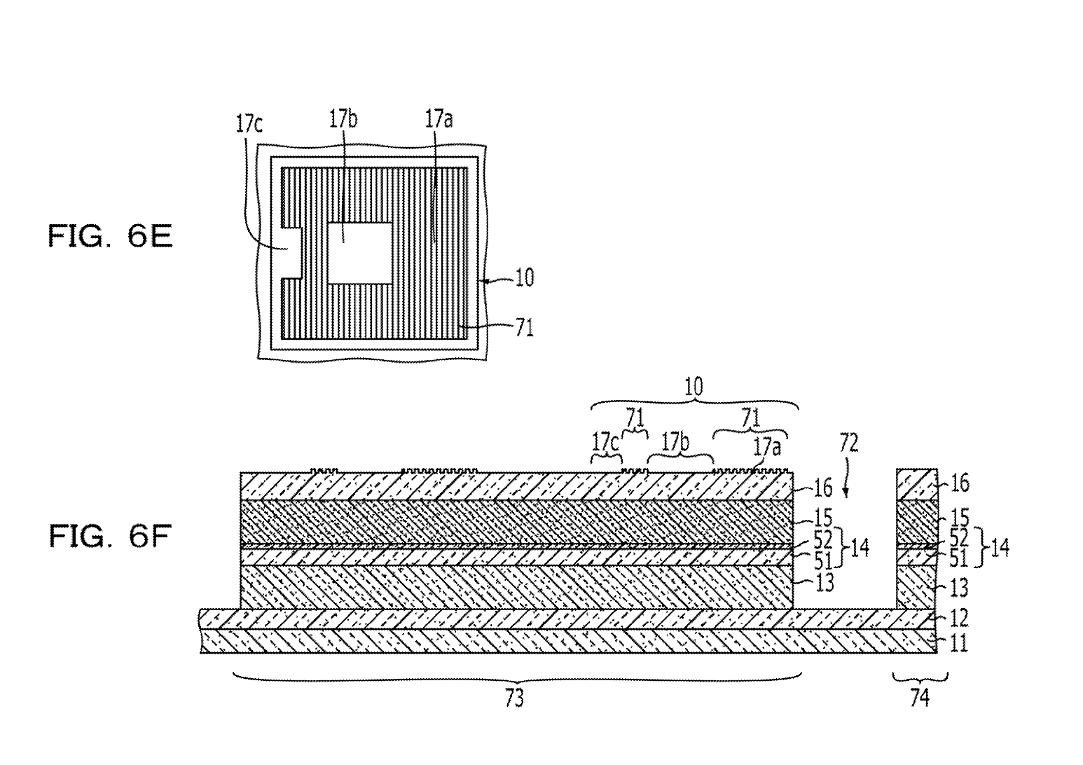

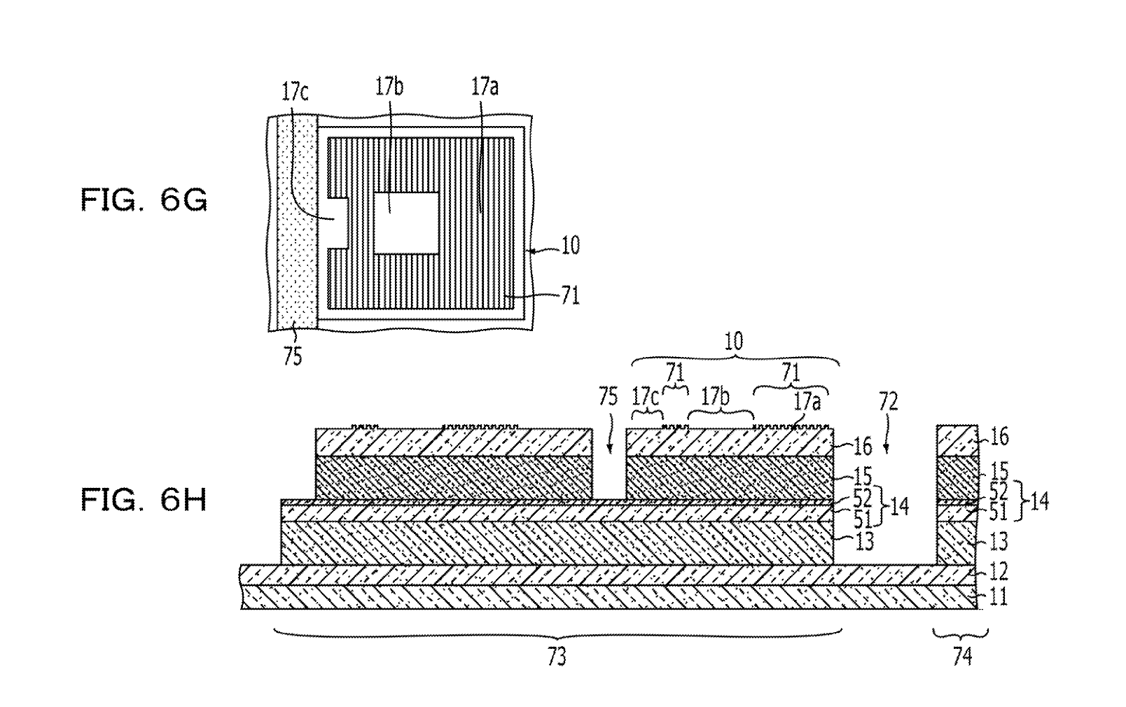

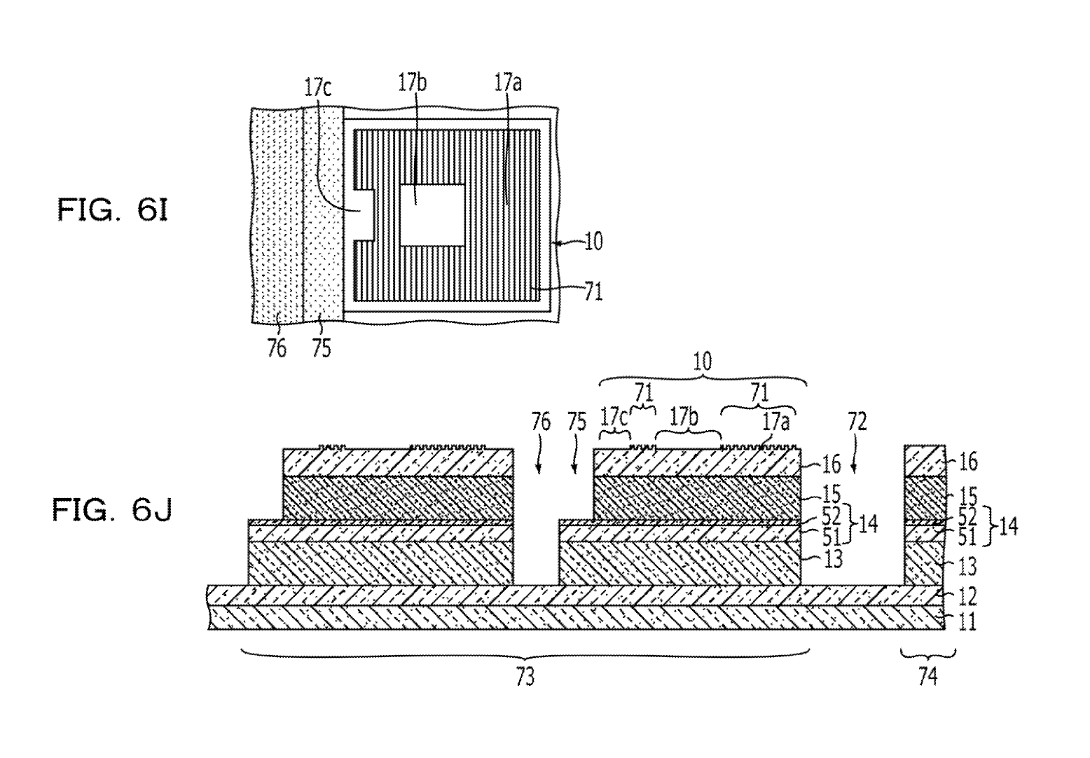

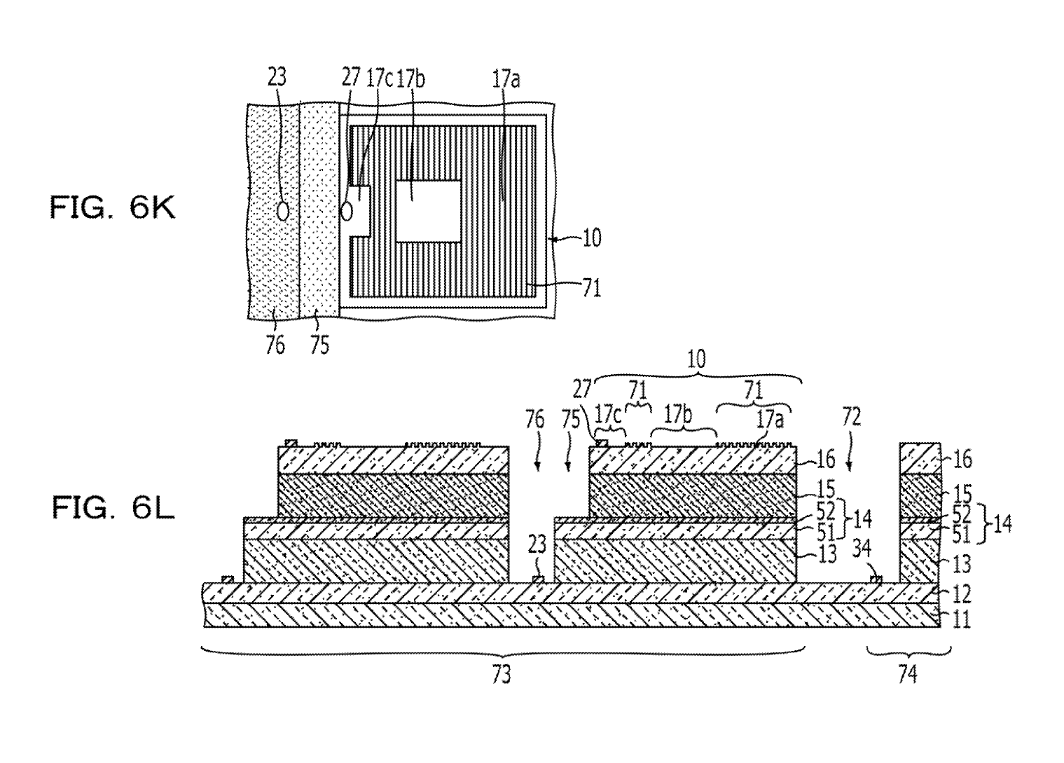

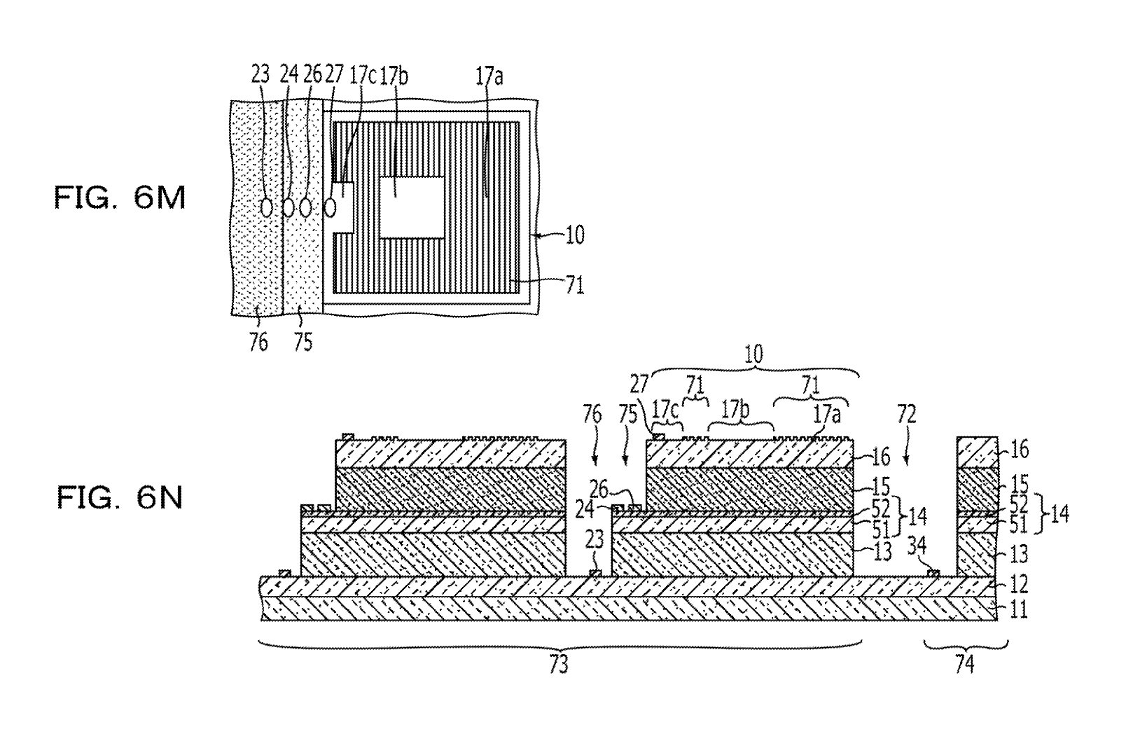

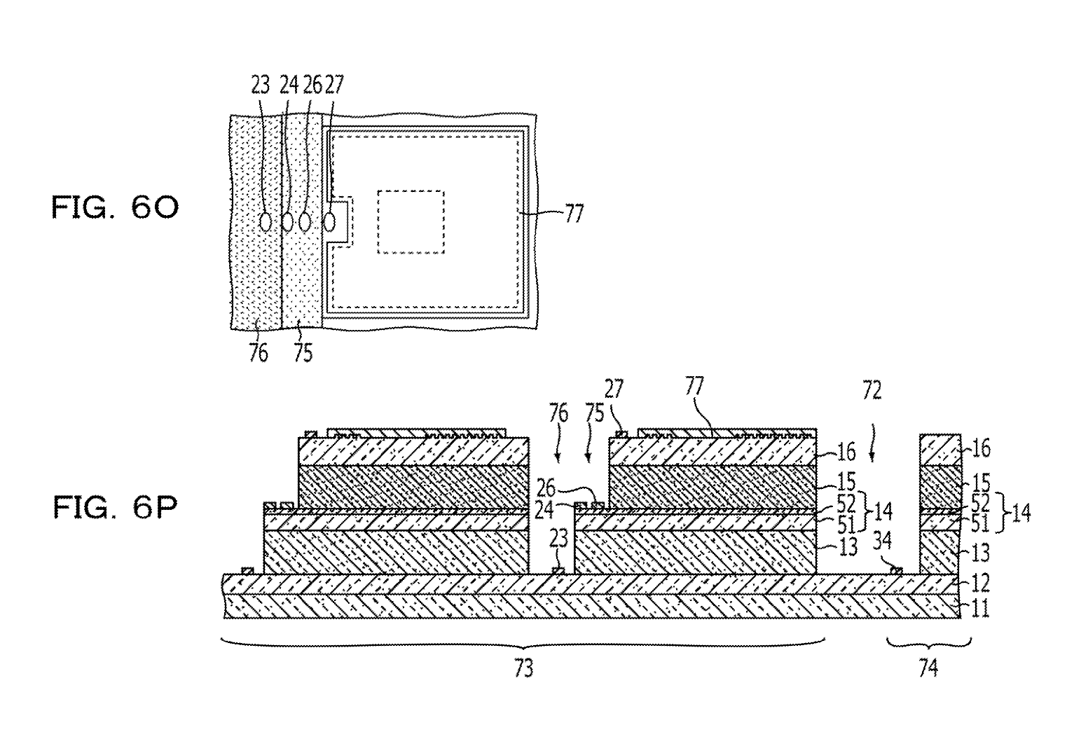

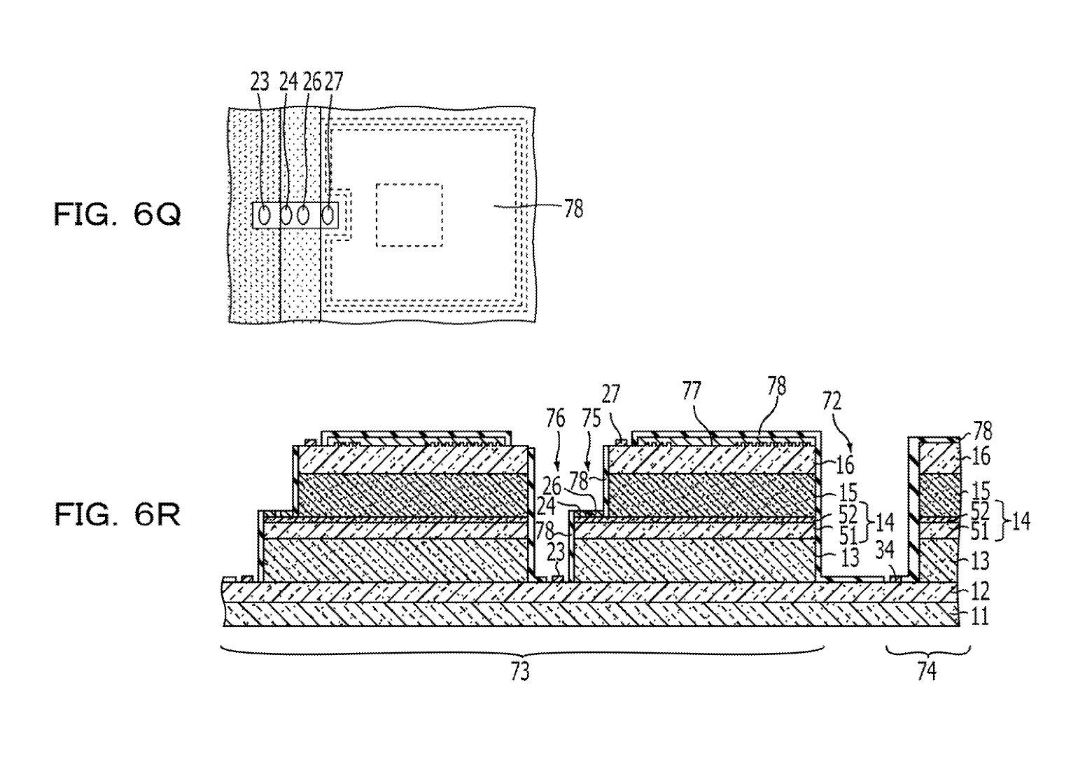

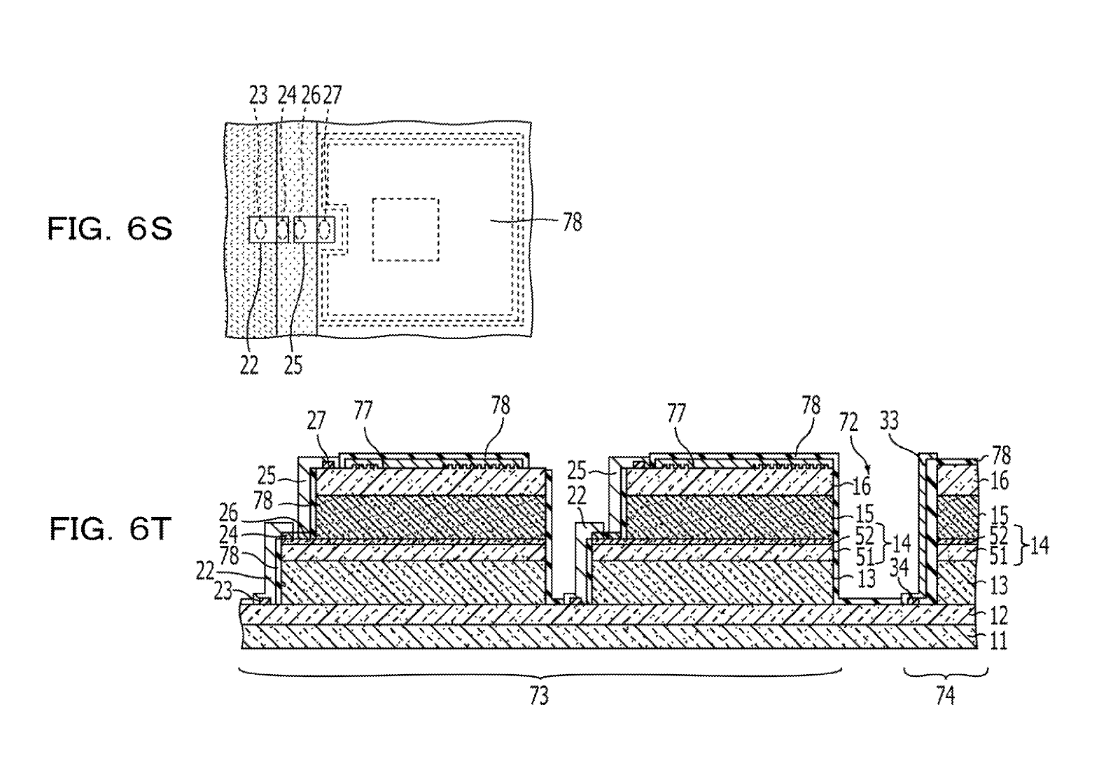

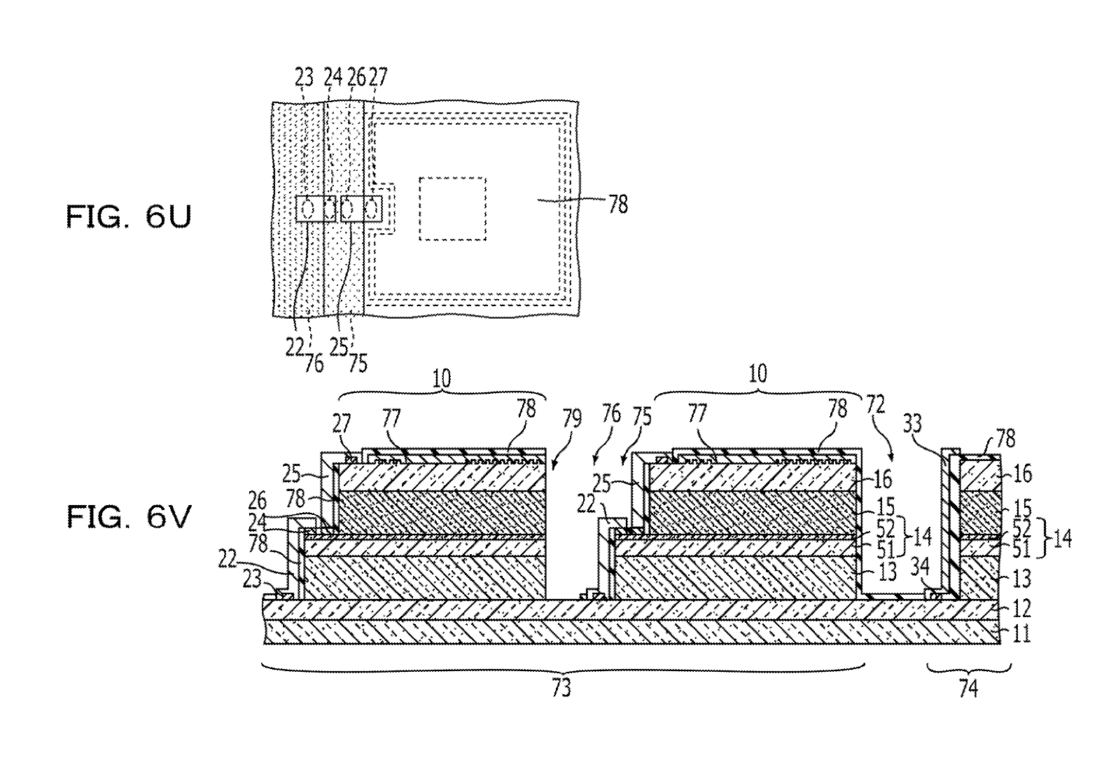

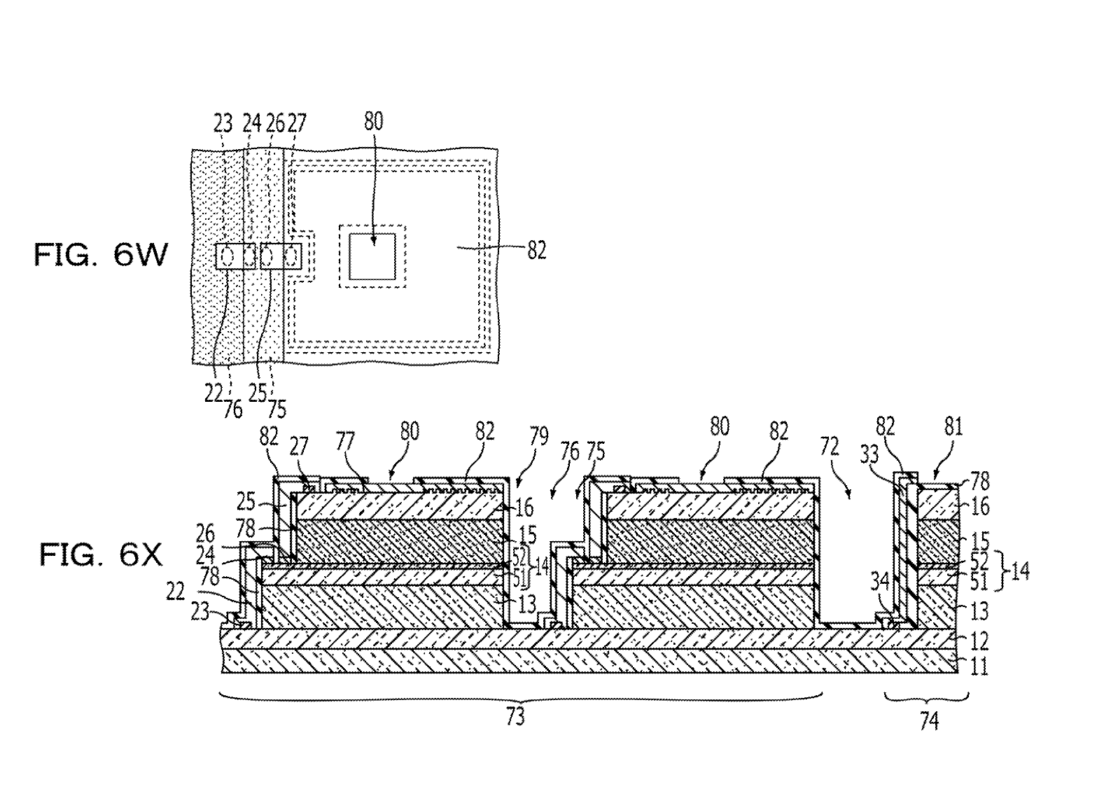

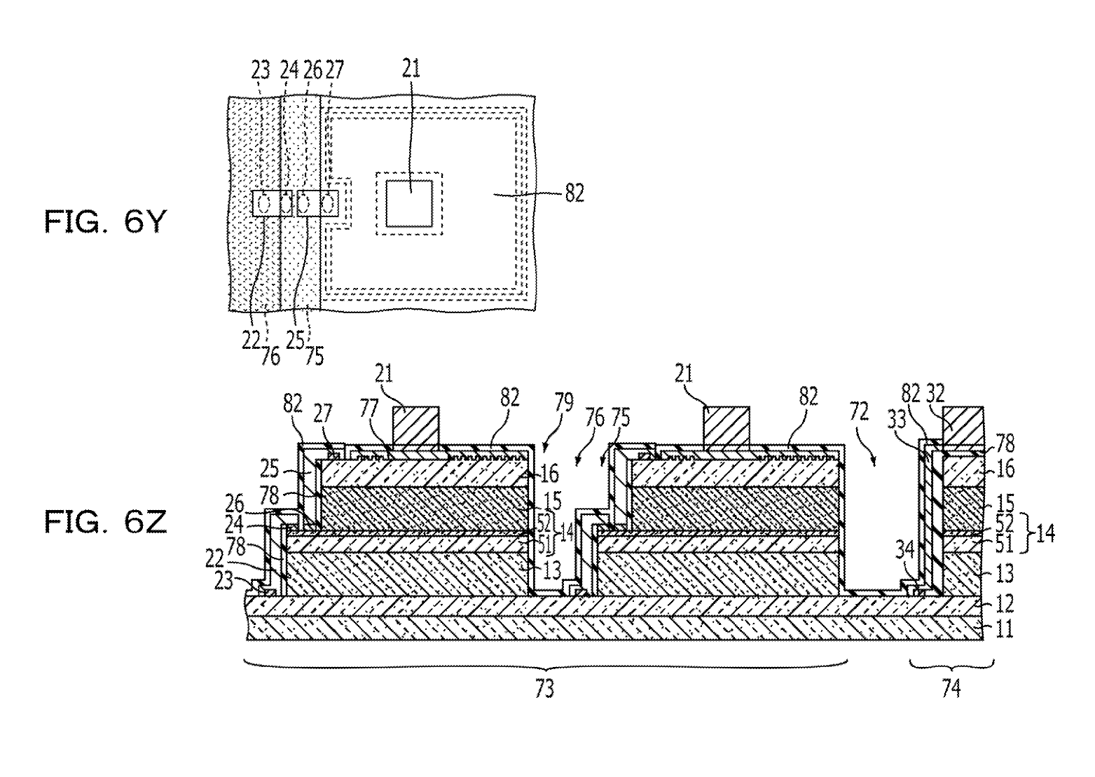

As depicted in FIG. 6A, a buffer layer (not depicted) may be first formed on the substrate 11 and then the lower electrode layer 12, the first light absorbing layer 13, a main intermediate electrode layer 51, a Schottky connection layer 52, the second light absorbing 15, and the upper electrode layer 16 may be laminated in that order. These layers may be each formed by having semiconductor layers undergo crystal growth or may be formed on the substrate 11 by a molecular beam epitaxy (MBE) process or metal organic chemical vapor deposition (MOCVD) process. The intermediate electrode layer 14 may be formed with the main intermediate electrode layer 51 and Schottky connection layer 52.

The semiconductor layers formed in this way will be described in more detail with reference to FIG. 6B. The substrate 11 may be formed from GaAs, and the buffer layer (not depicted) formed on the substrate 11 may be formed from GaAs or AlGaAs.

The lower electrode layer 12 may be formed by forming an n-type GaAs layer about 1000 nm thick that is doped with Si, which is used as an impurity element, with a doping level of 1.0×10¹⁸ cm⁻³.

The first light absorbing layer 13 may be formed so as to have a quantum well structure in which 20 barrier layers 61 and 20 well layers 62 are alternately laminated. The barrier layer 61 may be formed as an Al_{0.3}Ga_{0.7}As layer about 30 nm thick. The well layer 62 may be formed as an n-type Ga_{0.8}In_{0.2}As layer about 3 nm thick doped with Si, which is used as an impurity element, with a doping level of 5.0×10¹⁸ cm⁻³.

The main intermediate electrode layer 51 may be formed as an n-type GaAs layer about 1000 nm thick doped with Si, which is used as an impurity element, with a doping level of 1.0×10¹⁸ cm⁻³. The Schottky connection layer 52 may be formed as an n-type GaAs layer about 100 nm thick doped with Si, which is used as an impurity element, with a doping level of 1.0×10¹⁶ cm⁻³. As described above, the intermediate electrode layer 14 may be formed with the main intermediate electrode layer 51 and Schottky connection layer 52.

The second light absorbing 15 may be formed by forming a quantum well structure in which 20 barrier layers 63 and 20 well layers 64 are alternately laminated. The barrier layer 63 may be formed as an Al_{0.25}Ga_{0.75}As layer about 50 nm thick. The well layer 64 may be formed as an n-type GaAs layer about 5 nm thick doped with Si, which is used as an impurity element, with a doping level of 2.0×10¹⁷ cm⁻³.

The upper electrode layer 16 may be formed as an n-type GaAs layer about 1000 nm thick doped with Si, which is used as an impurity element, with a doping level of 1.0×10¹⁸ cm⁻³.

Next, ridges and trenches may be formed on the upper electrode layer 16 as illustrated in FIGS. 6C and 6D. Specifically, a photoresist may be applied to the surface of the upper electrode layer 16, and may be exposed to light and developed by a lithography apparatus so that a resist pattern (not illustrated) having openings is formed in an area, on the surface of the upper electrode layer 16, in which the trenches will be formed. After that, the trenches may be formed by performing dry etching such as reactive ion etching (RIE) to remove the upper electrode layer 16 to a predetermined depth in an area in which the resist pattern is not formed. Furthermore, the resist pattern (not illustrated) may then be removed by using an organic solvent or the like. A portion 17a of the trenches formed in this way and non-etched ridges may form a diffraction grating structure 71. Another portion 17b of the trenches may be an area in which an electrode part described later is formed. Another portion 17c of the trenches may be an area in which an electrode wire described later may be formed. FIG. 6C is a plan view of a portion including one pixel area 10 in this process, and FIG. 6D is a cross sectional view in this process.

Next, a groove 72 may be formed between the pixel forming area 73 and the non-pixel area 74 as illustrated in FIGS. 6E and 6F. Specifically, a photoresist may be applied to the surface of the upper electrode layer 16, and may be exposed to light and developed by a lithography apparatus so that a resist pattern (not illustrated) having an opening is formed in an area in which the groove 72 will be formed. After that, the groove 72 may be formed by performing dry etching such as RIE for the first light absorbing layer 13, main intermediate electrode layer 51, Schottky connection layer 52, second light absorbing 15, and upper electrode layer 16 in an area in which the resist pattern is not formed. Dry etching may be performed until the surface of the lower electrode layer 12 is exposed, after which the resist pattern (not illustrated) may be removed by using an organic solvent or the like. The groove 72 may separate the semiconductor layers formed on the substrate 11 into a pixel forming area 73, in which a plurality of pixel areas 10 are formed, and a non-pixel area 74, in which the electrode part 32 used as a common bias electrode terminal described later is formed. FIG. 6E is a plan view of a portion including one pixel area 10 in this process, and FIG. 6F is a cross sectional view in the process.

Next, a hole 75 may be formed to intercouple the intermediate electrode layer 14 and upper electrode layer 16 as illustrated in FIGS. 6G and 6H. Specifically, a photoresist may be applied to the surface of the upper electrode layer 16, and may be exposed to light and developed by a lithography apparatus so that a resist pattern (not illustrated) having an opening is formed in an area in which the hole 75 will be formed. After that, the hole 75 may be formed by performing dry etching such as RIE for the second light absorbing 15 and upper electrode layer 16 in an area in which the resist pattern is not formed. Dry etching may be performed until the surface of the Schottky connection layer 52 is exposed, after which the resist pattern (not illustrated) may be removed by using an organic solvent or the like. FIG. 6G is a plan view of a portion including one pixel area 10 in this process, and FIG. 6H is a cross sectional view in the process.

Next, a hole 76 may be formed to intercouple the lower electrode layer 12 and intermediate electrode layer 14 as illustrated in FIGS. 6I and 6J Specifically, a photoresist may be applied to the surface of the upper electrode layer 16, and may be exposed to light and developed by a lithography apparatus so that a resist pattern (not illustrated) having an opening is formed in an area in which the hole 76 will be formed. After that, the hole 76 may be formed by performing dry etching such as RIE for the first light absorbing layer 13, main intermediate electrode layer 51, Schottky connection layer 52, second light absorbing 15, and upper electrode layer 16 in an area in which the resist pattern is not formed. Dry etching may be performed until the surface of the lower electrode layer 12 is exposed, after which the resist pattern (not illustrated) may be removed by using an organic solvent or the like. FIG. 6I is a plan view of a portion including one pixel area 10 in this process, and FIG. 6J is a cross sectional view in the process.

Next, as illustrated in FIGS. 6K and 6L, the ohmic contact 27 may be formed on the upper electrode layer 16, the ohmic contact 23 may be formed in an area, on the lower electrode layer 12, that is exposed due to the hole 76, and the ohmic contact 34 may be formed in an area, on the lower electrode layer 12, that is exposed due to the groove 72.

Specifically, a photoresist may be applied to the surface of the upper electrode layer 16 and the surface of the lower electrode layer 12, and may be exposed to light and developed by a lithography apparatus so that a resist pattern (not illustrated) having openings are formed in an area in which the ohmic contacts 23, 27, and 34 will be formed. After that, a metal layer in which Au/Ge and Au are laminated may be formed by a vacuum deposition process or the like, and the metal layer formed on the resist pattern (not illustrated) may be removed together with the resist pattern by immersion into an organic solvent during a liftoff. Accordingly, the ohmic contact 27 may be formed on the upper electrode layer 16, and the ohmic contacts 23 and 34 may be formed on the lower electrode layer 12. FIG. 6K is a plan view of a portion including one pixel area 10 in this process, and FIG. 6L is a cross sectional view in this process.

Next, the Schottky contacts 24 and 26 may be formed in an area, on the Schottky connection layer 52 in the intermediate electrode layer 14, that is exposed due to the hole 75, as illustrated in FIGS. 6M and 6N. Specifically, a photoresist may be applied to the surface of the Schottky connection layer 52, and may be exposed to light and developed by a lithography apparatus so that a resist pattern (not illustrated) having openings are formed in an area in which the ohmic contacts 24 and 26 will be formed. After that, an Al layer may be formed by a vacuum deposition process or the like, and the Al layer formed on the resist pattern (not illustrated) may be removed together with the resist pattern by, for example, immersion into an organic solvent during a liftoff. Accordingly, the Schottky contacts 24 and 26 may be formed on the Schottky connection layer 52. FIG. 6M is a plan view of a portion including one pixel area 10 in this process, and FIG. 6N is a cross sectional view in this process.

Next, a reflective layer 77 may be formed in a prescribed area on the upper electrode layer 16, as illustrated in FIGS. 6O and 6P. Specifically, a photoresist may be applied to the surface of the upper electrode layer 16, and may be exposed to light and developed by a lithography apparatus so that a resist pattern (not illustrated) having an opening is formed in an area in which the reflective layer 77 will be formed. After that, an Au layer may be formed by a vacuum deposition process, and the Au layer formed on the resist pattern (not illustrated) may be removed together with the resist pattern by immersion into an organic solvent or the like during a liftoff. Thus, the reflective layer 77 may be formed in the prescribed area on the upper electrode layer 16. FIG. 6O is a plan view of a portion including one pixel area 10 in this process, and FIG. 6P is a cross sectional view in this process.

Next, an insulating layer 78 having an opening is formed in an area in which the ohmic contacts 23, 27, and 34 and the Schottky contacts 24 and 26 may be formed as illustrated in FIGS. 6Q and 6R. Specifically, an SiN layer may be formed as an insulating layer on the surface of the reflective layer 77 by chemical vapor deposition (CVD) or sputtering. After that, a photoresist may be applied to the surface of the formed insulating layer, and may be exposed to light and developed by a lithography apparatus so that a resist pattern (not illustrated) having an opening is formed in an area in which the SiN layer will be removed. Then, the insulating layer 78 may be formed by removing the SiN layer in an area in which the resist pattern is not formed by RIE or another type of dry etching and removing the resist pattern with an organic solvent or the like. The insulating layer 78 formed in the non-pixel area 74 may be equivalent to the insulating layer 31 illustrated in FIG. 3.

Next, the first electrode wire 22, second electrode wire 25, and electrode wire 33 may be formed as illustrated in FIGS. 6S and 6T. Specifically, a metal layer formed of Ti/Au may be formed on the surface of the insulating layer 78 by sputtering, after which the metal layer may be removed, by ion milling, from areas other than areas in which the first electrode wire 22, second electrode wire 25, and electrode wire 33 will be formed. Accordingly, the second electrode wire 25 may be formed on the ohmic contact 27 and Schottky contact 26 to intercouple them. Similarly, the first electrode wire 22 may be formed on the ohmic contact 23 and Schottky contact 24 to intercouple them.

The second electrode wire 25 may be ohmically coupled to the upper electrode layer 16 through the ohmic contact 27. Since a Schottky barrier is formed between the Schottky connection layer 52 and the Schottky contact 26, the second electrode wire 25 may be coupled to the intermediate electrode layer 14 through the Schottky barrier diode formed with the Schottky connection layer 52 and the Schottky contact 26.

The first electrode wire 22 may be ohmically coupled to the lower electrode layer 12 through the ohmic contact 23. Since a Schottky barrier is formed between the Schottky connection layer 52 and the Schottky contact 24, the first electrode wire 22 may be coupled to the intermediate electrode layer 14 through the Schottky barrier diode formed with the Schottky connection layer 52 and the Schottky contact 24. Furthermore, the electrode wire 33 coupled to the electrode part 32 described later may be formed on the ohmic contact 34, and the electrode wire 33 may be ohmically coupled to the lower electrode layer 12 through the ohmic contact 34.

Next, a pixel separating groove 79 may be formed as illustrated in FIGS. 6U and 6V. Specifically, a photoresist may be applied to the surface of the insulating layer 78, and may be exposed to light and developed by a lithography apparatus so that a resist pattern (not illustrated) having an opening is formed in an area in which the pixel separating groove 79 will be formed. After that, the first light absorbing layer 13, main intermediate electrode layer 51, Schottky connection layer 52, second light absorbing 15, upper electrode layer 16, and insulating layer 78 may then be removed, by RIE or another type of dry etching, from areas in which the resist pattern is not formed. Furthermore, the resist pattern (not illustrated) may then be removed by using an organic solvent or the like. Thus, the pixel separating groove 79 may be formed between pixel areas 10.

Next, an insulating layer 82 may be formed as illustrated in FIGS. 6W and 6X, which has an opening 80 in an area in which the electrode part 21 will be formed and also has an opening 81 in an area in which the electrode part 32 and electrode wire 33 are mutually coupled. Specifically, an insulating layer formed of SiN may be formed on the surfaces on which the first electrode wire 22, the second electrode wire 25, and the like are formed by sputtering or CVD. After that, a photoresist may be applied to the formed insulating layer, and may be exposed to light and developed by a lithography apparatus so that a resist pattern (not illustrated) having openings are formed in an area in which the opening 80 and opening 81 will be formed. Furthermore, the insulating layer may then be removed, by RIE or another type of dry etching, from areas in which the resist pattern is not formed, and the resist pattern may be removed by using an organic solvent or the like. Thus, the insulating layer 82 having the opening 80 and opening 81 may be formed.

Next, as illustrated in FIGS. 6Y and 6Z, the electrode part 21 may be formed in the opening 80 and the electrode part 32 may be formed in the opening 81. Specifically, a photoresist may be applied to the surface of the insulating layer 82, and may be exposed to light and developed by a lithography apparatus so that a resist pattern (not illustrated) having openings are formed in an area in which the electrode part 21 and electrode part 32 will be formed. After that, a base metal layer formed of Ti/Pt and a metal layer formed of In may by laminated by a vacuum deposition process. The base metal layer and metal layer may be removed from the area in which the resist pattern is formed by immersion into an organic solvent or the like during a liftoff. Thus, the electrode part 21 may be formed in the opening 80 and the electrode part 32 may be formed in the opening 81.

The photo detector in this embodiment may be manufactured as described above. The photodetector manufactured in this embodiment may be used after the electrode part 21 and electrode part 32 have been coupled to a CMOS read circuit in a hybrid manner. If a bias voltage is applied so that the electrode part 32 has a smaller electric potential than the electrode part 21, a current corresponding to the amount of light with a wavelength of about 5.0 μm is output, the light being detected in the second light absorbing 15. If a bias voltage is applied so that the electrode part 32 has a higher electric potential than the electrode part 21, a current corresponding to the amount of light with a wavelength of about 9.0 μm is output, the light being detected in the first light absorbing layer 13. Accordingly, it is possible to separately detect two infrared light rays having different wavelengths, which are a light ray with a wavelength of about 9.0 μm and a light ray with a wavelength of about 5.0 μm.

Although, in this embodiment, the photodetector in which the first light absorbing layer 13 and second light absorbing 15 are formed so as to have a quantum well structure, the first light absorbing layer 13 and second light absorbing 15 may be formed of a semiconductor layer that has a single composition rather than a quantum well structure. Furthermore, even if the first light absorbing layer 13 and second light absorbing 15 have a quantum wire structure, a quantum box structure, or the like, substantially the same effect may be obtained. Although, in this embodiment, a GaAs substrate has been used as the substrate 11 in the description of the photodetector having a structure in which a GaAs-based layer is formed, even if a Si substrate or InP substrate is used as the substrate 11, a photodetector having a similar structure may be obtained. When a Si substrate is used as the substrate, a semiconductor layer made of a Si-based material may be formed on the Si substrate. When an InP substrate is used as the substrate, a semiconductor layer made of an InP-based material may be formed on the InP substrate.

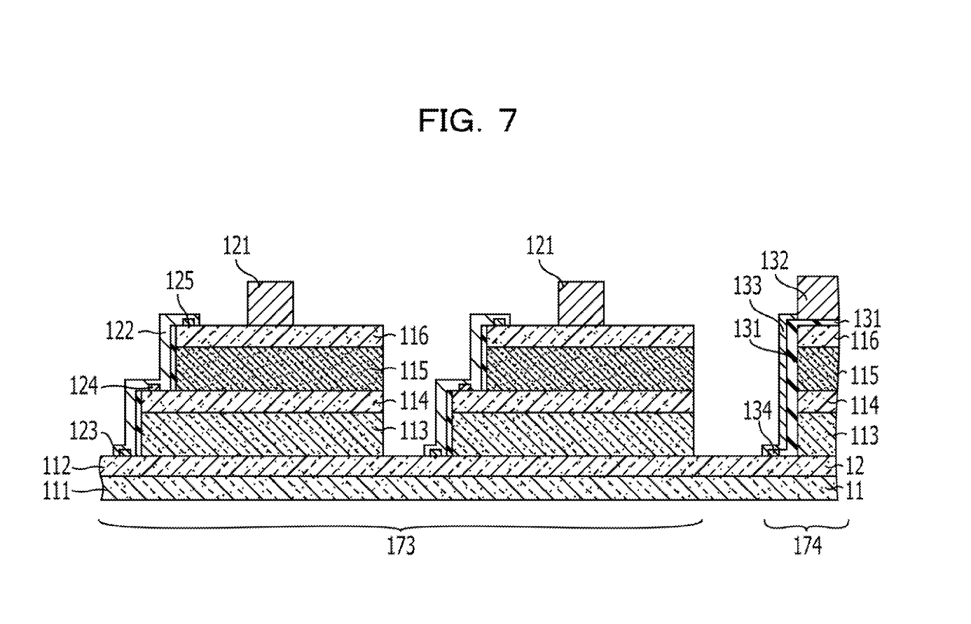

Next, a second embodiment will be described. A photodetector in this embodiment may have a different structure from the photodetector in the first embodiment. The structure of an image sensor that may detect two infrared rays with different wavelengths, which is the photodetector in this embodiment, will be described with reference to FIG. 7.

The infrared image sensor in the embodiment may have a substrate 111 such as a semiconductor on which a lower electrode layer 112, a first light absorbing layer 113, an intermediate electrode layer 114, a second light absorbing 115, and an upper electrode layer 116 may be laminated in that order. In this embodiment, the lower electrode layer 112 may be a first electrode layer, the intermediate electrode layer 114 may be a second electrode layer, and the upper electrode layer 116 may be a third electrode layer.

On the upper electrode layer 116 in a pixel forming area 173, one electrode part 121 called a bump, which is made of a metal material or another material, may be formed for each pixel. The electrode part 121 may be coupled to the upper electrode layer 116. An electrode wire 122 may be provided between the upper electrode layer 116 and the intermediate electrode layer 114 and between the intermediate electrode layer 114 and the lower electrode layer 112. A Schottky contact 123 may be provided between the electrode wire 122 and the lower electrode layer 112, and a Schottky barrier diode may be formed therebetween. An ohmic contact 124 may be provided between the electrode wire 122 and the intermediate electrode layer 114 and an ohmic contact may be provided therebetween. A Schottky contact 125 may be provided between the electrode wire 122 and the upper electrode layer 116, and a Schottky barrier diode may be formed therebetween.

In a non-pixel area 174, an electrode part 132 may be formed on the upper electrode layer 116 with an insulating layer 131 intervening therebetween, and an electrode wire 133 for intercoupling the lower electrode layer 112 and electrode part 132 may be provided. An ohmic contact 134 may be provided between the electrode wire 133 and lower electrode layer 112, and they may be ohmically coupled to each other. The electrode part 132 may be a common bias electrode terminal and may not be provided for each pixel. Accordingly, in the infrared image sensor in this embodiment, the electrode parts formed for each pixel may be the electrode part 121 alone, so the number of electrode parts formed per pixel may be one.

In general, the lower electrode layer 112, intermediate electrode layer 114, and upper electrode layer 116 may be each formed as a low-resistance semiconductor doped with an impurity at a high density to about 10×10¹⁸ cm⁻³. However, there are cases in which it is hard for a semiconductor layer doped with an impurity element at a high density to provide a superior Schottky barrier junction. In the lower electrode layer 112, therefore, a Schottky connection layer doped with an impurity element at a low density may be formed in a portion with which the Schottky contact 123 is brought into contact so that a Schottky barrier junction is provided. Similarly, in the upper electrode layer 116, a Schottky connection layer doped with an impurity element at a low density may be formed in a portion with which the Schottky contact 125 is brought into contact so that a Schottky barrier junction is provided.

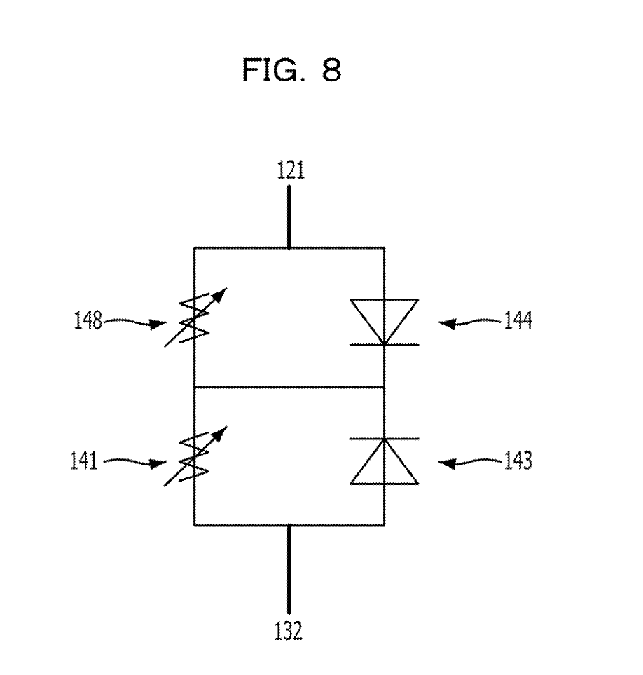

FIG. 8 depicts an equivalent circuit of the photodetector in this embodiment. A first photodetector part 141 may be formed with the lower electrode layer 112, the first light absorbing layer 113, and the intermediate electrode layer 114, and a second photodetector part 142 may be formed with the intermediate electrode layer 114, the second light absorbing 115, and the upper electrode layer 116. A first Schottky barrier diode 143 may be formed with the lower electrode layer 112 and the Schottky contact 123. A second Schottky barrier diode 144 may be formed with the upper electrode layer 116 and the Schottky contact 125. The first Schottky barrier diode 143 may be a first diode and the second Schottky barrier diode 144 may be a second diode.

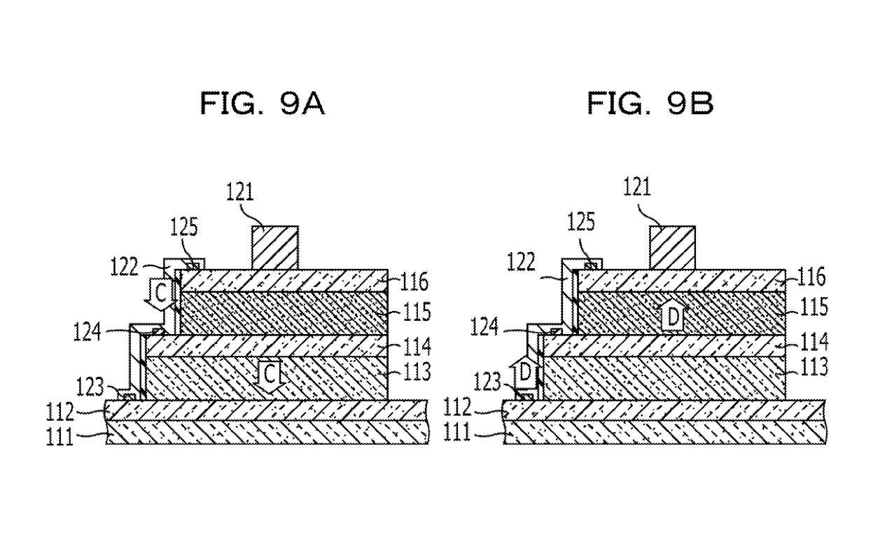

If, in this photodetector, a bias voltage is applied so that the electrode part 132 has a smaller electric potential than the electrode part 121, a current flows in the first photodetector part 141 and second Schottky barrier diode 144. This makes it possible to obtain an output corresponding to light detected by the first photodetector part 141. FIG. 9A indicates a current flow by using an arrow C while the photodetector in this embodiment is placed in this state. If a bias voltage is applied so that the electrode part 132 has a higher electric potential than the electrode part 121, a current flows in the second photodetector part 142 and first Schottky barrier diode 143. This makes it possible to obtain an output corresponding to light detected by the second photodetector part 142. FIG. 9B indicates a current flow by using an arrow D while the photodetector in this embodiment is placed in this state.

A switchover may be made between the output detected by the first photodetector part 141 and the output detected by the second photodetector part 142 by changing the bias voltage applied between the electrode part 121 and the electrode part 132 from the positive level to the negative level and vice versa as described above. Accordingly, one electrode part formed for one pixel is enough to obtain an infrared image sensor that may detect two infrared rays having different wavelengths.

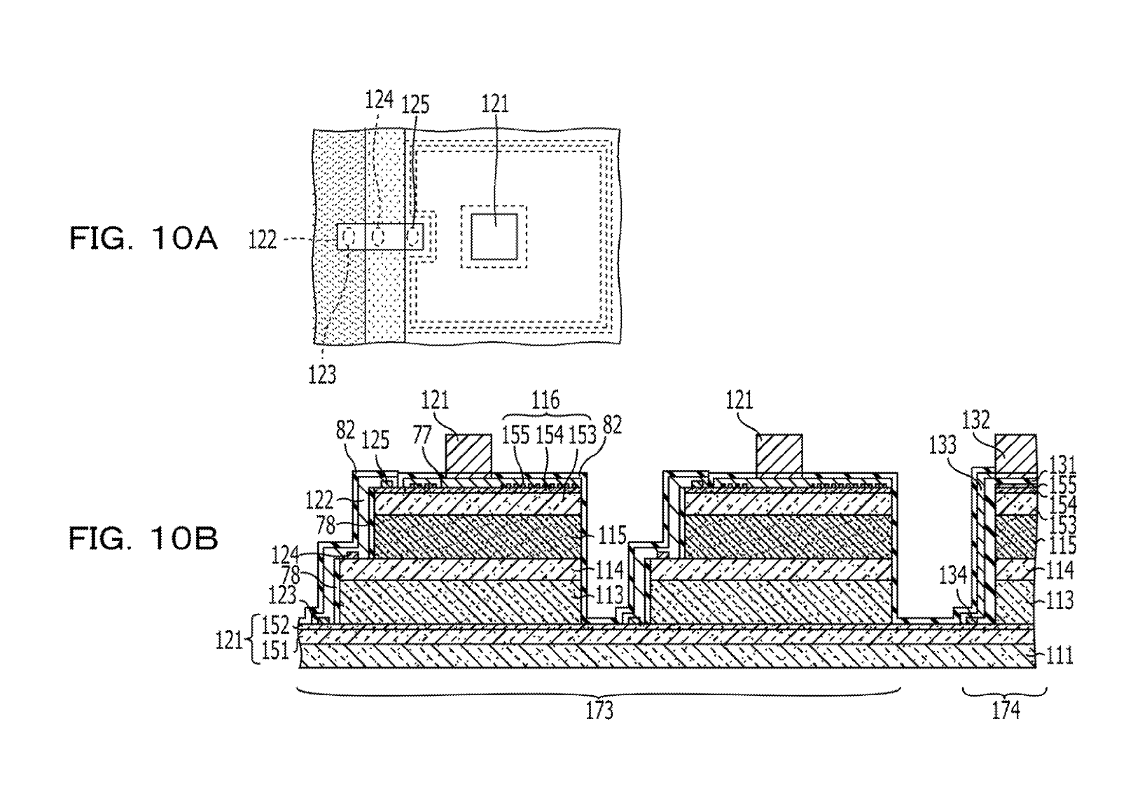

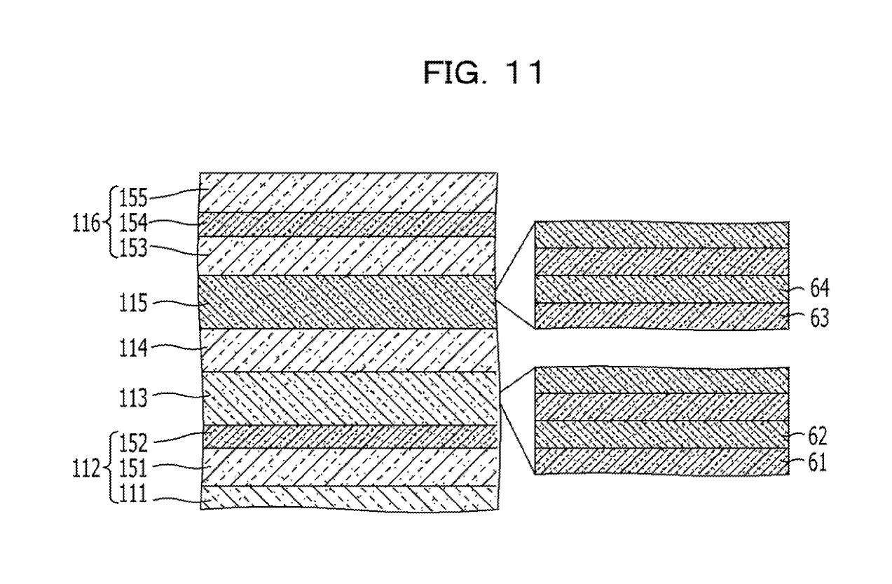

The photodetector in this embodiment will be described in more detail with reference to FIGS. 10A, 10B, and 11. FIG. 10A is a plan view of the major components of the photodetector in this embodiment, and FIG. 10B is a cross sectional view of them. The photodetector in this embodiment may have a buffer layer (not depicted) on the substrate 111, and the lower electrode layer 112, first light absorbing layer 113, intermediate electrode layer 114, second light absorbing 115, and upper electrode layer 116 may be laminated on the buffer layer in that order. These layers may be formed by having semiconductor layers undergo crystal growth or may be formed on the substrate 111 by an MBE process or MOCVD process.

The substrate 111 may be formed from insulating GaAs, and the buffer layer (not depicted) formed on the substrate 111 may be formed from GaAs or AlGaAs.

The lower electrode layer 112 may be formed with a main lower electrode layer 151 and a Schottky connection layer 152. The main lower electrode layer 151 may be formed by forming an n-type GaAs layer about 1000 nm thick that is doped with Si, which is used as an impurity element, with a doping level of 1.0×10¹⁸ cm⁻³. The Schottky connection layer 152 may be formed by forming an n-type GaAs layer about 100 nm thick that is doped with Si, which is used as an impurity element, with a doping level of 1.0×10¹⁶ cm⁻³.

The first light absorbing layer 113 may have substantially the same structure as the first light absorbing layer 13 in the first embodiment; the first light absorbing layer 113 may be formed by alternately laminating 20 barrier layers 61 and 20 well layers 62. The barrier layer 61 may be formed as an Al_{0.3}Ga_{0.7}As layer about 30 nm thick. The well layer 62 may be formed as an n-type Ga_{0.8}In_{0.2}As layer about 3 nm thick doped with Si, which is used as an impurity element, with a doping level of 5.0×10¹⁸ cm⁻³.

The intermediate electrode layer 114 may be formed as an n-type GaAs layer about 1000 nm thick doped with Si, which is used as an impurity element, with a doping level of 1.0×10¹⁸ cm⁻³.

The second light absorbing 115 may have substantially the same structure as the second light absorbing 15 in the first embodiment; the second light absorbing 115 may be formed by alternately laminating 20 barrier layers 63 and 20 well layers 64. The barrier layer 63 may be formed as an Al_{0.25}Ga_{0.75}As layer about 50 nm thick. The well layer 64 may be formed as an n-type GaAs layer about 5 nm thick doped with Si, which is used as an impurity element, with a doping level of 2.0×10¹⁷ cm⁻³.

The upper electrode layer 116 may be formed with a main upper electrode layer 153, a Schottky connection layer 154, and a coupler layer 155. The main upper electrode layer 153 may be formed as an n-type GaAs layer about 300 nm thick doped with Si, which is used as an impurity element, with a doping level of 1.0×10¹⁸ cm⁻³. The Schottky connection layer 154 may be formed as an n-type GaAs layer about 100 nm thick doped with Si, which is used as an impurity element, with a doping level of 1.0×10¹⁶ cm⁻³. The coupler layer 155 may be formed as an n-type GaAs layer about 800 nm thick doped with Si, which is used as an impurity element, with a doping level of 1.0×10¹⁸ cm⁻³. A diffraction grating is formed on the surface of the coupler layer 155, so the reflective layer 77 may be formed to have the coupler layer 155 function as a mirror. The electrode wire 122 may be formed on the ohmic contact 124 and the Schottky contacts 123 and 125 to mutually couple them. The insulating layer 78 may be formed on the sides of the lower electrode layer 112, first light absorbing layer 113, intermediate electrode layer 114, second light absorbing 115, main upper electrode layer 153, and Schottky connection layer 154. The electrode wire 122 may be formed outside the insulating layer 78. In the non-pixel area 174, the insulating layer 131 may be the insulating layer 78. The electrode wire 122 may be ohmically coupled to the intermediate electrode layer 114 through the ohmic contact 124 formed on the intermediate electrode layer 114. The Schottky contact 123 may be formed on the Schottky connection layer 152 in the lower electrode layer 112, and a Schottky barrier diode may be formed between the Schottky connection layer 152 and the Schottky contact 123. Therefore, the electrode wire 122 may be coupled to the lower electrode layer 112 through the Schottky barrier diode. The Schottky contact 125 may be formed on the Schottky connection layer 154 in the upper electrode layer 116, and a Schottky barrier diode may be formed between the Schottky connection layer 154 and the Schottky contact 125. Therefore, the electrode wire 122 may be coupled to the upper electrode layer 116 through the Schottky barrier diode. The ohmic contact 134 may be formed on the Schottky connection layer 152 in the non-pixel area 174, and the electrode wire 133 may be formed on the ohmic contact 134. Since the electrode wire 133 may be ohmically coupled to the lower electrode layer 112 through the ohmic contact 134 and the electrode wire 133 may be coupled to the electrode part 132, the electrode part 132 and lower electrode layer 112 may be mutually coupled.

The insulating layer 82 having openings may be formed in areas, on the electrode wire 122 and electrode wire 133, in which the electrode parts 121 and 132 will be formed. One electrode part 121 may be formed for each pixel on the reflective layer 77 formed in the pixel forming area 173 for each pixel, and the electrode part 132 may be formed in the non-pixel area 174.

The photodetector in this embodiment may be used after the electrode part 121 and electrode part 132 have been coupled to a CMOS read circuit in a hybrid manner. If a bias voltage is applied so that the electrode part 132 has a smaller electric potential than the electrode part 121, a current corresponding to the amount of light with a wavelength of about 9.0 μm is output, the light being detected in the first light absorbing layer 113. If a bias voltage is applied so that the electrode part 132 has a higher electric potential than the electrode part 121, a current corresponding to the amount of light with a wavelength of about 5.0 μm is output, the light being detected in the second light absorbing 115. Accordingly, it is possible to separately detect two infrared light rays having different wavelengths, which are a light ray with a wavelength of about 9.0 μm and a light ray with a wavelength of about 5.0 μm.

Structures not described above are substantially the same as in the first embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A photodector, comprising:
a substrate;
a first electrode layer, a first light absorbing layer, a second electrode layer, a second light absorbing layer, and a third electrode layer that are laminated on the substrate;
an electrode wire that intercouples the first electrode layer, the second electrode layer, and the third electrode layer;
a first diode formed at a place where the first electrode layer and the electrode wire are mutually brought into contact; and
a second diode formed at a place where the third electrode layer and the electrode wire are mutually brought into contact.

2. The photodector according to claim 1, wherein:
when a voltage applied to the first electrode layer is higher than a voltage applied to the third electrode layer, a current that corresponds to light detected in the second light absorbing layer flows; and
when a voltage applied to the first electrode layer is lower than a voltage applied to the third electrode layer, a current that corresponds to light detected in the first light absorbing layer flows.

3. The photodector according to claim 1, wherein:
when a voltage applied to the first electrode layer is higher than a voltage applied to the third electrode layer, a current flows in the second light absorbing layer and the first diode; and
when a voltage applied to the first electrode layer is lower than a voltage applied to the third electrode layer, a current flows in the first light absorbing layer and the second diode.

4. The photodector according to claim 1, wherein the first electrode layer, the first light absorbing layer, the second electrode layer, the second light absorbing layer, and the third electrode layer are made of semiconductor materials.

5. The photodector according to claim 1, wherein the first electrode layer, the second electrode layer, and the third electrode layer are made of materials including GaAs, the materials are made of an n-type by being doped with an impurity.

6. The photodector according to claim 4, wherein:
the first diode is a Schottky barrier diode, the first diode being formed by forming, on the first electrode layer, a Schottky barrier junction that is coupled to the electrode wire; and
the second diode is a Schottky barrier diode, the second diode being formed by forming, on the third electrode layer, a Schottky barrier junction that is coupled to the electrode wire.

7. The photodector according to claim 6, wherein:
the first electrode layer has a first main electrode layer and a first Schottky connection layer;
the third electrode layer has a third main electrode layer and a third Schottky connection layer;
the first Schottky connection layer is formed on a side on which the first electrode layer is coupled to the Schottky barrier junction, and the third Schottky connection layer is formed on a side on which the third electrode layer is coupled to the Schottky barrier junction; and
an impurity density in the first Schottky connection layer is lower than an impurity density in the first main electrode layer, and an impurity density in the third Schottky connection layer is lower than an impurity density in the third main electrode layer.

8. The photodector according to claim 6, wherein the Schottky barrier junction is made of a material including Al.

9. The photodector according to claim 4, wherein an ohmic contact is made between the second electrode layer and the electrode wire.
